(19) United States
(12) Patent Application Publication
(10) Pub. No.: US 2014/0109832 A1
(43) Pub. Date: Apr. 24, 2014

(54) DEPOSITION APPARATUS

(71) Applicant: ASM IP Holding B.V., Almere (NL)

(72) Inventors: Ki Jong KIM, Daejeon-si (KR); Dae Youn Kim, Daejeon (KR); Hyun Soo Jang, Daejeon (KR)

(73) Assignee: ASM IP Holding B.V., Almere (NL)

(21) Appl. No.: 14/057,160

(22) Filed: Oct. 18, 2013

(30) Foreign Application Priority Data
Oct. 23, 2012 (KR) 10-2012-0118062

(51) Int. Cl. C23C 16/452

(52) U.S. Cl. CPC C23C 16/452
USPC 118/723 R

(57) ABSTRACT

In a deposition apparatus, as a plurality of plasma connection terminals that transfer plasma power to a plasma electrode are coupled in parallel to the plasma electrode, resistance caused by the plurality of plasma connection terminals is reduced and a current is distributed such that heat generated in the plurality of plasma connection terminals can be distributed. Therefore, even if high RF power is used, by preventing the plurality of plasma connection terminals from being oxidized, plasma is stably supplied and thus, stability of a deposition apparatus and the accuracy of a process can be enhanced.

### CROSS-REFERENCE TO RELATED APPLICATION

This application claims priority to and the benefit of Korean Patent Application No. 10-2012-0118062 filed in the Korean Intellectual Property Office on Oct. 23, 2012, the entire contents of which are incorporated herein by reference.

### BACKGROUND OF THE INVENTION

(a) Field of the Invention

The present invention relates to a deposition apparatus.

(b) Description of the Related Art

As a method of depositing a thin film on a silicon substrate, a physical vapor deposition (PVD) method and a chemical vapor deposition (CVD) method have been used.

However, as the size of a semiconductor device becomes smaller, existing deposition methods showed limitation. As a next generation deposition method to replace the existing deposition method, an atomic layer deposition (ALD) method has been developed and the ALD method is currently widely used.

In the ALD method, a thin film is deposited on a substrate by a self-limiting process, and the process is performed at a temperature range in which pyrolysis is not performed and a chemical reaction between reaction gases occurs. Therefore, the ALD method has an advantage in that thin film deposition is possible at a low temperature compared to the existing conventional CVD method.

The ALD method includes a thermal ALD method and a plasma enhanced ALD method. In the thermal ALD method, a reaction between reaction gases on a substrate is activated by thermal energy supplied from a heater, which supports the substrate, to the substrate. In the plasma enhanced ALD method, a reaction between reaction gases is induced by supplying plasma to a reaction space other than a heater thermal source. In the plasma enhanced ALD method, when a plasma is supplied to a reaction gas that is difficult to react in the conventional thermal atomic layer deposition method, a reaction can be easily induced so that films having various qualities can be deposited although such a process would be difficult to achieve in the conventional thermal ALD method. Currently, research and application thereof have been actively performed.

Among deposition apparatuses using plasma, as a method to increase efficiency of plasma compared to a conventional method in which plasma is provided remotely, an in-situ plasma deposition apparatus, which generates plasma directly within a reaction space by having a plasma electrode that transfers the plasma define the reaction space inside of a reactor, has been developed.

In a plasma atomic layer deposition process, stable supply of plasma is very important. In the plasma atomic layer deposition process, plasma is intermittently supplied for a short time that is less than a few seconds during which a reaction gas is supplied. When such a process is repeated, overheating of an RF rod occurs. The RF rod transfers the plasma, which is generated in an RF plasma generator, to a plasma electrode that is installed at an upper end portion of the reaction space. Therefore, overheating of the RF rod results in reduced accuracy of the process and affects stability of the deposition apparatus.

Further, in a process in which high RF power is necessary, as RF power increases, high current flows at the RF rod and at a connection portion positioned between the RF rod and the plasma electrode, and thus, the RF rod and the connection portion may be oxidized.

The above information disclosed in this Background section is only for enhancement of understanding of the background of the invention and therefore it may contain information that does not form the prior art that is already known in this country to a person of ordinary skill in the art.

### SUMMARY OF THE INVENTION

The present invention has been made in an effort to provide a deposition apparatus having advantages of enhanced stability and enhanced accuracy of a process by stably supplying plasma by preventing a plasma connection terminal from being oxidized, even if high RF power is provided to the deposition apparatus using plasma power.

An exemplary embodiment of the present invention provides a deposition apparatus including: a substrate support; a plasma electrode that defines a reaction space by being coupled to the substrate support; a plasma power source portion that supplies plasma power to the plasma electrode; and a plurality of plasma connection terminals that are connected between the plasma power source portion and the plasma electrode.

The plurality of plasma connection terminals may be coupled in parallel between the plasma power source portion and the plasma electrode.

The plurality of plasma connection terminals may each have the same resistance.

The plurality of plasma connection terminals may be symmetrically disposed with respect to the plasma electrode.

There may be two plasma connection terminals in a deposition apparatus according to an exemplary embodiment of the present invention.

In a deposition apparatus according to an exemplary embodiment of the present invention, as a plurality of plasma connection terminals that transfer plasma power to a plasma electrode are coupled in parallel to the plasma electrode, resistance caused by the plasma connection terminal is reduced, and a current is distributed such that heat generated in the plasma connection terminal can be distributed. Therefore, even if high RF power is provided, by preventing a plasma connection terminal from being oxidized, plasma is stably supplied, and thus, stability of a deposition apparatus and the accuracy of a process can be enhanced.

### BRIEF DESCRIPTION OF THE DRAWINGS

FIG. 1 is a cross-sectional view illustrating a deposition apparatus according to an exemplary embodiment of the present invention.

FIG. 2 is a diagram illustrating resistance that is applied to a plasma connection terminal of the deposition apparatus according to an exemplary embodiment of the present invention.

FIG. 3 is a table illustrating results of an experimental example of the deposition apparatus according to an exemplary embodiment of the present invention.

### DETAILED DESCRIPTION OF THE EMBODIMENTS

The present invention will be described more fully hereinafter with reference to the accompanying drawings, in which exemplary embodiments of the invention are shown. As those skilled in the art would realize, the described embodiments may be modified in various different ways, all without departing from the spirit or scope of the present invention.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

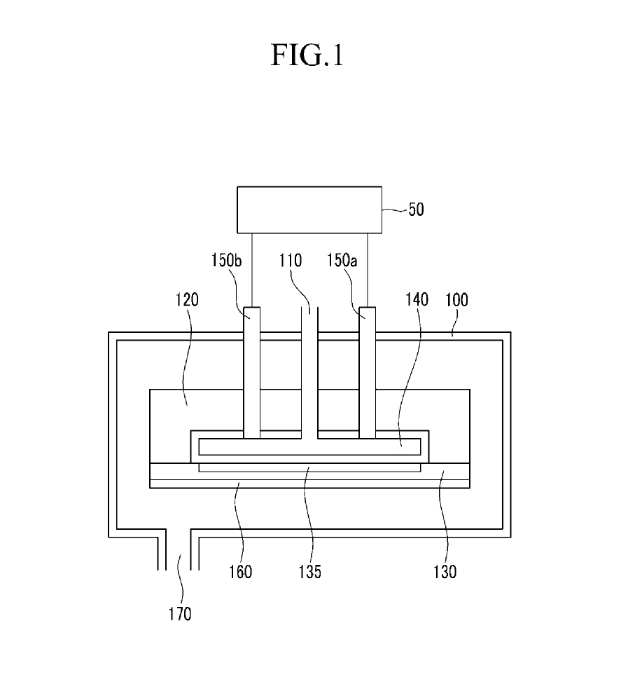

Hereinafter, a deposition apparatus according to an exemplary embodiment of the present invention will be described with reference to FIG. 1. FIG. 1 is a cross-sectional view illustrating a deposition apparatus according to an exemplary embodiment of the present invention.

Referring to FIG. 1, the deposition apparatus according to an exemplary embodiment of the present invention includes an outer wall 100, a gas inflow pipe 110, a reaction chamber wall 120, a substrate support 130, a plasma electrode 140 that defines a reaction space together with the substrate support 130, a plurality of plasma connection terminals 150a and 150b that transfer high RF power to the plasma electrode 140, and a plasma power source 50 that is connected to the plasma connection terminals 150a and 150b.

Each constituent element will now be described in detail.

The outer wall 100 of the deposition apparatus prevents heat being lost from the inside of a reaction chamber to the outside.

A substrate 135, which is a deposition target, is disposed at the substrate support 130, and a heater 160 is disposed under the substrate support 130. The heater 160 raises the temperature of the substrate 135 up to a temperature that is necessary for a process.

The reaction chamber wall 120 and the substrate support 130 are in close contact for a deposition process, and together they define a reaction chamber.

The gas inflow pipe 110 is inserted into the plasma electrode 140, and the plasma connection terminals 150a and 150b are connected to the plasma electrode 140. In the present exemplary embodiment, one gas inflow pipe 110 is illustrated, but a plurality of gas inflow pipes may be included, and different process gases may be individually injected through the plurality of gas inflow pipes.

During the deposition process, the substrate support 130 and the substrate 135 function as an opposite electrode with respect to the plasma electrode 140. Although not shown in the drawing, power may be supplied to the substrate support 130 through an additional plasma connection terminal.

A deposition apparatus according to an exemplary embodiment of the present invention includes the plurality of plasma connection terminals 150a and 150b that are connected to the plasma electrode 140, and the plurality of plasma connection terminals 150a and 150b are coupled in parallel to the plasma power source 50. The plurality of plasma connection terminals 150a and 150b may be symmetrically disposed with respect to the plasma electrode 140. The number of plasma connection terminals 150a and 150b may be two or more.

When a process gas is injected through the gas inflow pipe 110 and a voltage of the plasma power source 50 is applied to the plasma electrode 140 through the plurality of plasma connection terminals 150a and 150b, a process gas that is injected into a reaction chamber is changed to plasma due to a difference in voltage between the plasma electrode 140 and the substrate support 130 and the plasma is deposited on the substrate 135.

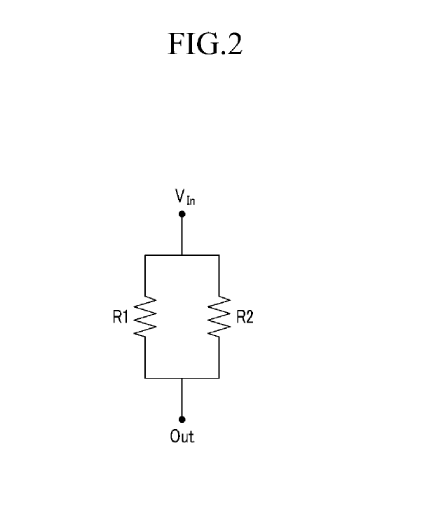

Hereinafter, a connection relationship between the plasma power source 50, the plasma connection terminals 150a and 150b, and the plasma electrode 140 of a deposition apparatus according to an exemplary embodiment of the present invention, and voltage and current values according to plasma power supply according to the connection relationship will be described with reference to FIGS. 1 and 2. FIG. 2 is a diagram illustrating resistance that is applied to a plasma connection terminal of the deposition apparatus according to an exemplary embodiment of the present invention.

As described with reference to FIG. 1, the deposition apparatus according to an exemplary embodiment of the present invention includes the plurality of plasma connection terminals 150a and 150b that are connected to the plasma electrode 140, and the plurality of plasma connection terminals 150a and 150b are coupled in parallel to the plasma power source 50.

Referring to FIG. 2, a principle of resistance of the plurality of plasma connection terminals 150a and 150b that are connected to the plasma electrode 140 of the deposition apparatus according to an exemplary embodiment of the present invention will now be described. The plurality of plasma connection terminals 150a and 150b that are connected to the plasma electrode 140 of the deposition apparatus according to an exemplary embodiment of the present invention are coupled in parallel to the plasma power source 50. When resistances of the plurality of plasma connection terminals 150a and 150b that are connected to the plasma power source 50 are R1 and R2, respectively, and a total resistance value RT of the plurality of plasma connection terminals 150a and 150b, which are coupled in parallel and applied to the plasma power source 50, is determined as follows.

$${R}_{T} = \frac{{R}_{1} {R}_{2}}{{R}_{1} + {R}_{2}}$$

Therefore, when values of a resistor R of the plurality of plasma connection terminals 150a and 150b that are connected to the plasma power source 50 are the same, the total resistance value RT becomes R/N according to the number N of the plurality of plasma connection terminals 150a and 150b.

A current is proportional to a voltage that is applied to an input terminal and is inversely proportional to a resistance value according to the formula I=V/R (V: voltage, I: current, R: resistance). Resistance reduces current flow and generates heat when a current flows. As the plurality of plasma connection terminals 150a and 150b that are connected to the plasma electrode 140 of an apparatus according to the present exemplary embodiment are coupled in parallel rather than in series as in the conventional deposition apparatus, a value of resistance that is applied to the plasma power source 50 is reduced compared to coupling in series without changing a sectional area of the plasma connection terminals 150a and 150b, and thus, even if a magnitude of a voltage of an input terminal V_{In} is maintained, a magnitude of a current flowing from the input terminal V_{In} to an output terminal Out increases compared to the coupling in series.

Further, according to the following formula of a power law,

P=VI cos θ,(P:RFpower,V:voltage,I:current,cos θ:power factor(0−1)),

as plasma power increases, a voltage and a current increase, and when a sufficient quantity of current cannot flow through the plasma connection terminals 150a and 150b, contact resistance between the plasma connection terminals 150a and 150b and the plasma electrode 140 increases, and thus, much heat is generated.

However, a deposition apparatus according to an exemplary embodiment of the present invention includes a plurality of plasma connection terminals 150a and 150b that are coupled in parallel between the plasma electrode 140 and the plasma power source 50, and thus, a resistance value according to the plurality of plasma connection terminals 150a and 150b is reduced compared to coupling in series, and an entire current can be distributed through the plurality of plasma connection terminals 150a and 150b. Therefore, generated heat can be distributed to the plurality of plasma connection terminals 150a and 150b, and thus, heat generated in each of the plasma connection terminal 150a and 150b is reduced.

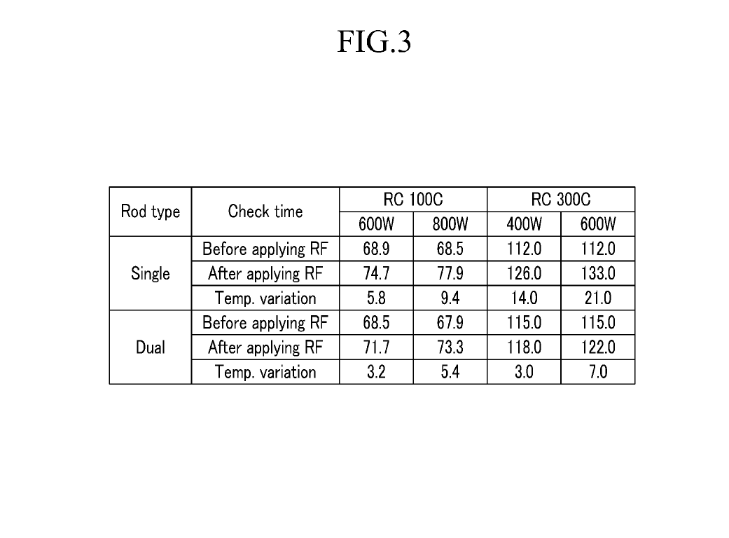

Hereinafter, a result according to an experimental example of the present invention will be described with reference to FIG. 3. FIG. 3 is a table illustrating a result of an experimental example of the deposition apparatus according to an exemplary embodiment of the present invention.

In this experimental example, a case in which one plasma connection terminal is connected between a plasma power source and a plasma electrode in series (single) and a case in which two plasma connection terminals are coupled in parallel (dual) are provided. In these cases, when the temperature of a reactor is set to about 100° C. (RC 100 C), plasma power of 600 W and 800 W are supplied and when the temperature of a reactor is set to about 300° C. (RC 300 C), plasma power of 400 W and 600 W are supplied. Temperature variations of the plasma connection terminals before and after plasma power is applied are as shown in FIG. 3.

Referring to FIG. 3, it can be seen that in the case in which one plasma connection terminal is connected between the plasma power source and the plasma electrode in series (single), as in the conventional deposition apparatus, as the reactor temperature rises, a variation in temperature (Temp. variation) of the plasma connection terminal, before and after plasma power is applied, is increased, and when the same reactor temperature is maintained, as intensity of supplied plasma power increases, the variation in temperature (Temp. variation) of the plasma connection terminal, before and after plasma power is applied, is increased.

It can also be seen that in the case in which two plasma connection terminals are coupled in parallel (dual), as in a deposition apparatus according to an exemplary embodiment of the present invention, a variation in temperature (Temp. variation) of the plasma connection terminal, before and after plasma power is applied, is reduced, compared with the case in which one plasma connection terminal is connected between a plasma power source and a plasma electrode (single) as in the conventional deposition apparatus.

Further, it can be seen that in the case in which two plasma connection terminals are coupled in parallel (dual), as in a deposition apparatus according to an exemplary embodiment of the present invention, as a value of plasma power increases, a variation in temperature (Temp. variation) of the plasma connection terminal, before and after plasma power is applied, is reduced significantly, compared with the case in which one plasma connection terminal is connected between the plasma power source and the plasma electrode as in the conventional deposition apparatus.

As demonstrated above, in the deposition apparatus according to an exemplary embodiment of the present invention, since a plurality of plasma connection terminals that transfer plasma power to the plasma electrode is connected to a plasma electrode in parallel, resistance of the plasma connection terminal is reduced and a current is distributed, and thus, heat generated in the plasma connection terminal can be distributed. Therefore, even if high RF power is used, by preventing a plasma connection terminal from being oxidized due to the heat, plasma can be stably supplied, thus, enhancing stability of the deposition apparatus and the accuracy of a process.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A deposition apparatus, comprising:
a substrate support;
a plasma electrode coupled to the substrate support such that the coupled substrate support and plasma electrode define a reaction space;
a plasma power source portion that supplies plasma power to the plasma electrode; and
a plurality of plasma connection terminals that are connected between the plasma power source portion and the plasma electrode.

2. The deposition apparatus of claim 1, wherein the plurality of plasma connection terminals are coupled in parallel between the plasma power source portion and the plasma electrode.

3. The deposition apparatus of claim 2, wherein resistance of each of the plurality of plasma connection terminals is the same.

4. The deposition apparatus of claim 3, wherein the plurality of plasma connection terminals are symmetrically disposed about the plasma electrode.

5. The deposition apparatus of claim 4, wherein a number of the plurality of plasma connection terminals is two.

6. The deposition apparatus of claim 1, wherein resistance of each of the plurality of plasma connection terminals is the same.

7. The deposition apparatus of claim 6, wherein the plurality of plasma connection terminals are symmetrically disposed about the plasma electrode.

8. The deposition apparatus of claim 7, wherein a number of the plurality of plasma connection terminals is two.

9. The deposition apparatus of claim 1, wherein the plurality of plasma connection terminals are symmetrically disposed about the plasma electrode.

10. The deposition apparatus of claim 9, wherein a number of the plurality of plasma connection terminals is two.
